(19) United States
(12) Patent Application Publication
(10) Pub. No.: US 2026/0028289 A1
(43) Pub. Date: Jan. 29, 2026

(54) NATURAL STONE PANEL WITH AN INTEGRATED TOUCH SENSING SYSTEM AND MANUFACTURING METHOD THEREOF

(71) Applicants: CENTITVC - CENTRO DE NANOTECNOLOGIA E MATERIAIS TÉCNICOS FUNCIONAIS E INTELIGENTES, VILA NOVA DE FAMALICÃO (PT); SOLANCIS - SOCIEDADE EX PLORADORA DE PEDREIRAS, S.A, BENEDITA (PT)

(72) Inventors: José Fernando OLIVEIRA DA SILVA, VILA NOVA DE FAMALICÃO (PT); Andre Filipé FERNANDES DA SILVA ANDRADE LEITE, VILA NOVA DE FAMALICÃO (PT); Daniela Cristina RODRIGUES CAMPANHÃ, VILA NOVA DE FAMALICÃO (PT); Samuel COSTA DELGADO, BENEDITA (PT); Nelson Manuel PAULINO DA SILVA, CALVARIA DE CIMA (PT)

(73) Assignees: CENTITVC - CENTRO DE NANOTECNOLOGIA E MATERIAIS TÉCNICOS FUNCIONAIS E INTELIGENTES, VILA NOVA DE FAMALICÃO (PT); SOLANCIS - SOCIEDADE EX PLORADORA DE PEDREIRAS, S.A, BENEDITA (PT)

(21) Appl. No.: 18/995,689

(22) PCT Filed: Apr. 28, 2023
(86) PCT No.: PCT/IB2023/054460

§ 371 Date: Jan. 16, 2025

(30) Foreign Application Priority Data
Jul. 26, 2022 (PT) 118126

(51) Int. Cl. C04B 41/71; C04B 41/00; C04B 41/48; C04B 41/51; C04B 41/63; C09D 11/037; C09D 11/52; G06F 3/044; H05K 1/02; H05K 1/09

(52) U.S. Cl. CPC C04B 41/71; C04B 41/009; C04B 41/4853; C04B 41/5111; C04B 41/63; C09D 11/037; C09D 11/52; G06F 3/0446; H05K 1/0218; H05K 1/092; G06F 2203/04103; G06F 2203/04107

(57) ABSTRACT

Natural stone panel with an integrated touch capacitive sensing system for placing as a touch detection facade, in direct contact with a wall, is disclosed. An embodiment includes: a natural stone tile; a printed sensing on said tile having a plurality of conductive tracks; a printed shielding on said tile having a plurality of conductive tracks; an insulating layer between the printed sensing layer and the wall; wherein the sensing tracks have been printed using a first ink, and the shielding tracks have been printed using a second ink, wherein electrical conductivity of the first ink is lower or equal than electrical conductivity of the second ink; wherein the printed sensing layer has two conductive zones, one square shaped, with an open interior, for detecting the touch events, and one rectangular shaped, to connect the control and power printed circuit board to the printed sensor.

### TECHNICAL DOMAIN

The present invention relates to a natural stone panel with touch sensing capabilities, for application in interior or exterior walls. In particular, it relates to a stone panel containing conductive sensing elements on its back, specifically, a capacitive sensor composed of printed conductive inks, capable of detecting alterations in the electrical field between two electrodes when a foreign body, in particular, a finger, is introduced making use of the Joule Effect. The printed capacitive sensor can be fully printed on the back of the stone tile.

### BACKGROUND

Touch sensors are commonly composed of one or more electrodes and an associated circuit that induces an electric field between the electrodes, detecting changes to the electric field when it's disturbed by a stimulus such as a user's touch or proximity. These components are typically disposed on a flat substrate, such as a printed circuit board, polymeric film or glass panel, and then attached to a second substrate, typically a nonconductive panel the face of a control panel, which is visible to the user of the device and a portion of which a user touches or approaches to disturb the induced electric field and thus trigger the touch sensor. This second substrate is typically used as the decorative layer and, at the same time, works as indicator to the presence and location of the underlying touch sensor. Such touch sensor assemblies protect the touch sensor and control circuitry from environmental conditions while providing an aesthetic face.

Analysing the available literature and patent databases, it was not possible to identify examples of touch sensing structures as the one described in the present invention, where the sensing layer is deposited directly in a stone structure, and, additionally, the examples of printed capacitive touch sensor presented different configurations for the sensor and/or the shielding layer. As for existing patents that describe similar systems to the ones proposed in this patent, the examples found are described next.

The first patent, US20060236624 A1, describes a concrete based, or concrete-like manmade stone-like structures, electronic control interface device, that is based in the introduction of signal pipes capable of transmitting light or electrical currents through the structure, in order to form human control surfaces that can be used to operate and monitoring one or more appliances by proxy, in conjunction with controllers that are connected to a hidden second surface(s) of the concrete structure.

The next patent, EP1446879B1, describes touch sensor assemblies with decorations disposed on the touch sensor assembly itself, and not on another substrate, in order to create an aesthetic and ergonomic control panel face. The decorations can be applied directly to the touch sensor substrate or on a separate carrier, such as a decal or film, and their purpose can be to alert the user of the touch sensor position and/or to alert the touch sensor user to the particular function or response of a particular operative touch surface.

Finally, patent WO2012052152A3, describes a sensor arrangement used for the detection of proximity and/or touching by, for example, a human finger. The sensing arrangement is composed of at least one sensor supporting surface, a proximity and/or touching sensor connected to said supporting surface, a decoration supporting medium and a decoration layer which is connected to the decoration supporting medium and/or is an integral component of the decoration supporting medium. The sensor element is based on an electrode integrally connected to the decoration layer, preferably by being printed on said decoration layer, that acts as part of a capacitor, with alterations of the internal capacitance indicating that an object, for example, a human finger, is located in the vicinity of the electrode.

These facts are described to illustrate the technical problem solved by the embodiments of the present document.

### General Description

This disclosure proposes a natural stone panel with a touch sensing system directly applied onto it, for the purpose of permitting its application as a touch detection system for facade applications, to permit the activation or control of other associated systems. The details will be described with reference to FIGS. 1 to 2.

As illustrated in FIG. 1, this natural stone panel according to an embodiment includes a limestone tile with printed capacitive sensor, wherein A) represents a sensing track; B) represents a shielding track; C) represents an insulating layer; D) represents a support polymeric layer; E) represents a stone tile.

This work was developed in the framework of INSTONE project, co-financed by the Operational Programme for Competitiveness and Internationalization (COMPETE 2020), under the PORTUGAL 2020 Partnership Agreement, through the European Regional Development Fund (ERDF).

This disclosure proposes a natural stone panel with an integrated touch sensing system for placing as a touch detection panel into direct contact with wall, comprising: a support stone panel or, interchangeably, a support stone tile; a printed sensing layer on said tile (whether printed directly or indirectly on said tile), comprising a plurality of conductive tracks that form the sensing electrode or shielding layer; an insulating layer for providing moisture and electrical insulation between the printed sensing electrode and the wall; wherein the printed electrode has two main sections, with the top section having a square shape and open interior, also in a square shape, being responsible for detection the touch event, and the bottom section, in a rectangular shape, being used to connect to the associated control printed circuit board; wherein the shielding layer is applied in a mesh configuration, with criss-crossed lines in a diagonal direction.

In an embodiment, the natural stone panel further comprises a polymeric layer for uniformizing a back surface of the support stone tile for receiving the printed sensing layer and reducing tile porosity, wherein the printed sensing layer is printed on said polymeric layer. In an embodiment, a polymeric layer for uniformizing a back surface of the support stone tile for reducing humidity ingress from a front face of the tile, thus reducing water risks to the electrical circuit, and also reducing conductive ink absorption, thus facilitating ink deposition and uniformity.

In an embodiment, the polymeric layer is a resin, in particular an epoxy resin.

In an embodiment, the resin is applied by dipping the back surface of the tile in said resin.

In an embodiment, the polymeric layer is a film.

In an embodiment, the film is a polyethylene terephthalate (PET), polyethylene terephthalate glycol-modified (PETG), and/or polyethylene naphthalate (PEN) film.

In an embodiment, the polymeric layer is electrically insulating.

In an embodiment, the distance between the shielding tracks and the sensing electrode is equal to the thickness of the stone tile section where the sensor is applied.

In an embodiment, the conductive sensing tracks comprise silver, copper, or other metallic elements, or combinations thereof.

In an embodiment, the conductive shield tracks comprise silver, copper, or other metallic elements, or combinations thereof.

In an embodiment, a natural stone panel further comprises an outer insulating polymeric layer for to protecting and isolating the printed sensing layer.

In an embodiment, the outer insulating layer comprises polyethylene terephthalate (PET), polyethylene terephthalate glycol-modified (PETG), polyethylene naphthalate (PEN), and/or polyimide.

In an embodiment, the outer insulating polymeric layer is moisture and electrically insulating.

In an embodiment, the support stone tile is a sedimentary rock, igneous rock, metamorphic rock, preferably a sedimentary rock, further preferably limestone, travertine, marble, granite, basalt, sandstone, gneiss, quartzite, slate, onyx or laterite, further preferably limestone. Along the disclosure, it is considered that a stone tile is a stone block or slab used for tiling.

In an embodiment, the sensing electrode square top section comprise a width and length of at least 2 cm and a thickness of at least 20 microns.

In an embodiment, the open interior of the top section of the sensing electrode comprises a width and length of at least 1 cm.

In an embodiment, the sensing electrode bottom section comprise a width of 2 mm, a length of at least 5 cm and a thickness of at least 20 microns.

In an embodiment, the shielding tracks are placed around the sensing electrode, at a distance of at least 1 cm.

In an embodiment, the shielding tracks occupy an area with a length of at least 9.5 cm and a width of at least 7.5 cm.

In an embodiment, the shielding tracks have a width of at least 1 mm and a thickness of at least 20 microns.

In an embodiment, the support stone panel of the natural stone panel comprises a porosity between 0.5% and 7%, preferably between 1% and 6%, measured using standard EN 1936:2006—“Natural stone test methods—Determination of real density and apparent density, and of total and open porosity”.

In an embodiment, the conductive tracks comprise materials with sheet resistivities comprised range between 10 mΩ/sq/mil and 20 mΩ/sq/mil.

It is also disclosed a method for manufacturing a natural stone panel with an integrated touch sensing system for placing as touch detection façade into direct contact with a wall, said method comprising: providing a support stone tile; printing a printed sensing layer on said tile, comprising a plurality of conductive tracks; curing of the silver and/or copper and/or aluminium tracks at temperatures comprised between 100° C. and 150° C., for 10 minutes to 20 minutes; printing a printed shielding layer on said tile, comprising a plurality of conductive tracks; curing of the silver and/or copper and/or aluminium tracks at temperatures comprised between 100° C. and 150° C., for 10 minutes to 20 minutes; applying an insulating layer for providing moisture and electrical insulation between the printed sensing layer and the wall; wherein the shielding and sensing tracks have been printed using the same or different conductive inks.

In an embodiment, the curing after the printing is done in dryers/ovens with ventilation.

In an embodiment, the method for manufacturing a natural stone panel further comprises the step of gluing a copper conductive tape on top of selected zones of the conductive tracks underneath the insulation layer.

In an embodiment, a plurality of copper wires is soldered to the copper tape and connected to a control circuit.

### BRIEF DESCRIPTION OF THE FIGURES

The following figures provide preferred embodiments for illustrating the disclosure and should not be seen as limiting the scope of invention.

FIG. 1. Illustrates a schematic representation of the cross section of a stone panel with printed sensing and shielding tracks, wherein A) represents a sensing track; B) represents a shielding track; C) represents an insulating layer; D) represents a support polymeric layer; E) represents a stone tile.

FIG. 2. Shows a schematic representation of the touch sensing elements applied to the support stone panel (not represented in the figure).

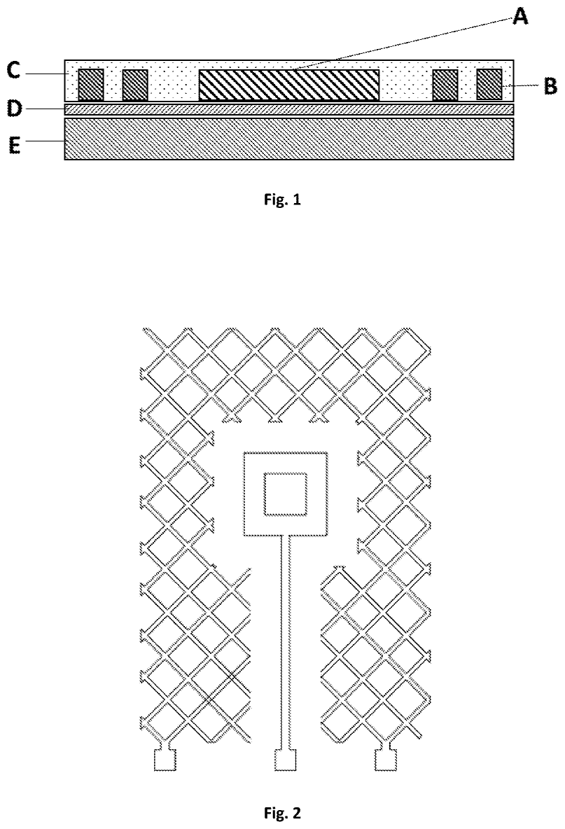

### DETAILED DESCRIPTION

The present disclosure refers to a natural stone panel with a touch sensing system directly applied onto it, for the purpose of the permitting its application as a capacitive touch detection system for façade applications.

In its most basic form, the final system can be composed of the support stone tile, a printed sensing layer, an insulating layer and the control and power hardware.

To accommodate the printed sensing layer and promote uniform printing, the stone element, e.g. limestone, should have a homogeneous distribution of mineral agglomerates and porosity, between 1% and 7%, measured using standard EN 1936:2006—“Natural stone test methods—Determination of real density and apparent density, and of total and open porosity”.

The sensing and shield layers can be directly printed on the stone back surface, but to prevent defects in the printed layers, due to, for example, pre-existing holes on the surface of the stone tile, a polymeric layer should be applied prior to the application of the printed layers, in order to fill in any hole or crack that might exist in the surface, which might then result in defects in the printed layers, as well as create a more uniform roughness, to prevent non-uniformity between, for example, the thickness of the printed tracks. This polymeric layer can be applied under the form of a liquid coating, for example, of an epoxy resin, that then is cured to become rigid, filling in the pores and creating a uniform surface, or under the form of a polymeric membrane, of polyethylene terephthalate (PET), and/or polyethylene naphthalate (PEN), that is glued onto the surface, for the same purpose. The substrates must resist the curing temperature of the conductive inks, usually comprised between 100° C. and 150° C. with an exposure time at temperatures comprised between 10 minutes and 20 minutes.

In the case of the polymeric membrane, the same material can also be used as the insulating layer. This layer prevents the sensing and shielding layer materials from coming into direct contact with the wall, which might damage it. Since this protection is made of a moisture and electrically insulating material, it prevents the conductive materials that composed the conductive layer from oxidizing, thus maintaining the system's efficiency and functionality.

In an embodiment, the printed sensing and shielding tracks can be composed of tracks created by printing the same or two different inks, based, for example, on silver, copper, or other metallic elements.

The conductive materials and/or inks used should be capable of being processed by screen printing technology, and/or rotogravure and/or inkjet printing. These conductive materials must present low sheet resistivity, with values comprised between 5 mΩ/sq/mil and 40 mΩ/sq/mil and, therefore, do not dissipate too much energy by Joule effect nor introduce electrical noise in the sensing circuit.

Regarding the design of the sensing circuit, for the present invention, it is composed of two layers, one from the shielding and grounding of the system, and one, the sensing electrode, for the detection of the touch events, both composed of conductive materials. In this geometry the system detects alterations in the capacitance between two electrodes, with the printed electrode being one of them and the human finger being the other, with the printed shielding layer, around the printed sensor, grounding the system and blocking electromagnetic interference from nearby electrical fields.

The printed sensor electrode should have a top section with a width and length of at least 2 cm, and a bottom section with a width of at least 2 mm and a length of at least 5 cm, with both sections having a thickness of at least 20 microns. As for the shielding tracks, they can have varying lengths, but a width of at least 1 mm. The shield tracks should end at a distance from the sensing electrode no less than the thickness of the section of the stone tile where they are printed.

The materials that compose the sensing and shielding circuits can be printed by any technique that allows the direct deposition of the necessary inks, taking into accounting their rheological properties, and according to a predetermined design. These techniques can be, for example, screen printing and/or rotogravure and/or inkjet printing, being the chosen printing technology, tailored to the inks available.

The shielding and sensing circuits can be printed in the same printing step, or in different ones, depending on if they are composed of the same ink or not.

When the technology selected is screen printing, the ink is forced to pass to the substrate through a frame which is perforated with the pattern that one wants to print out, this being constituted by polyester or metal. The steps for printing a touch sensing system through screen printing on a stone tile are as follows:
1. Printing of the silver and/or copper and/or aluminum tracks on the stone substrate to create the sensing electrode on the stone substrate or support membrane.
2. Thermal curing of the silver and/or copper and/or aluminum tracks at temperatures comprised between 100° C. and 150° C., for 10 minutes to 20 minutes.
3. Printing of the silver and/or copper and/or aluminum tracks on the stone substrate to create the shielding layer on the stone substrate or support membrane.
4. Thermal curing of the silver and/or copper and/or aluminum tracks at temperatures comprised between 100° C. and 150° C., for 10 minutes to 20 minutes.

The dimensions of the printed circuits, and the tracks that compose them, are defined by the frame used to make the printing. In this technique, the amount of material which is printed is defined by the characteristics of the frame and the processing parameters used. The curing of the material after the printing is done in dryers/ovens with ventilation.

To allow the connection of the printed shielding and sensing circuits to the control and power hardware, a copper conductive tape should be glued on top of selected sections of the conductive tracks, but below the insulation layer. The copper tape must have a width equal or higher than the width of the mentioned selected sections. Copper wires are then soldered to the copper tape and to connected to the control PCB.

The electronic control hardware is constituted by a power supply for the circuits, a control printed circuit board and an encapsulating material for electrical and mechanical protection.

Since the human body is grounded, when the user touches the surface of the stone tile, it causes fringing electric field lines to stray from the printed sensor to the hand, as the hand approaches the sensor. The capacitance increases as the hand gets closer to the sensor, but in a non-linear way because of fringing effects, with the changes in capacitance being detected by the control printed circuit board and interpreted as a touch event that then can be used to activate or alter another associated system, like a heating or lighting system. The presence of the shielding layer reduces EMI and parasitic capacitances effects.

For the current function of the sensing system, it's important the place where the sensing structures are applied, should not have a thickness greater than the separation between the sensing electrode, responsible for creating the electric field used for the detection of the approach or touch on the stone surface by the human finger, and the shielding silver mesh.

The term “comprising” whenever used in this document is intended to indicate the presence of stated features, integers, steps, components, but not to preclude the presence or addition of one or more other features, integers, steps, components or groups thereof.

The disclosure should not be seen in any way restricted to the embodiments described and a person with ordinary skill in the art will foresee many possibilities to modifications thereof. The above-described embodiments are combinable. The following claims further set out particular embodiments of the disclosure.

1. A natural stone panel with an integrated touch capacitive sensing system for placing as a touch detection facade, in direct contact with a wall, comprising:
a natural stone tile;
a polymeric layer on a back surface of the stone tile;
a printed touch-sensitive layer on said polymeric layer comprising a plurality of circuit tracks arranged to detect touch events on the stone tile;
a printed conductive layer on said polymeric layer comprising a plurality of shielding tracks to provide insulation from electromagnetic interference; and
an insulating layer for providing moisture and electrical insulation between the printed conductive layers and the wall;
wherein the sensing conductive tracks have been printed using a first ink, and the shielding conductive tracks have been printed using a second ink, wherein electrical conductivity of the first ink is lower or equal than electrical conductivity of the second ink, and
wherein the polymeric layer makes the back surface of the stone tile uniform for receiving the printed layers and for reducing panel porosity.

2. (canceled)

3. The natural stone panel according to claim 1, wherein the polymeric layer is a resin, in particular an epoxy resin.

4. The natural stone panel according to claim 12, wherein the resin is applied by dipping the back surface of the natural stone tile in said resin.

5. (canceled)

6. The natural stone panel according to claim 1, wherein the polymeric layer comprises a film which is selected from the group consisting of: a polyethylene terephthalate (PET), polyethylene terephthalate glycol-modified (PETG), and polyethylene naphthalate (PEN) film.

7. (canceled)

8. The natural stone panel according to claim 1, wherein the distance between the shielding tracks and the sensing tracks is no less than the thickness of the stone tile on which they are printed.

9. The natural stone panel according to claim 1, wherein the shielding tracks comprise silver, copper, or other metallic elements, or combinations thereof.

10. The natural stone panel according to claim 1, wherein the sensing tracks comprise silver, copper, or other metallic elements, or combinations thereof.

11. The natural stone panel according to claim 1, further comprising an outer insulating polymeric layer for protecting and isolating the printed sensing layer.

12. (canceled)

13. The natural stone panel according to claim 11, wherein the outer insulating layer is selected from the group consisting of: polyethylene terephthalate (PET), polyethylene terephthalate glycol-modified (PETG), polyethylene naphthalate (PEN), and polyimide.

14. The natural stone panel according to claim 1, wherein the stone tile is a sedimentary rock, igneous rock, metamorphic rock.

15. (canceled)

16. The natural stone panel according to claim 1, wherein the sensing electrode square top section comprises a thickness of at least 20 microns.

17. (canceled)

18. (canceled)

19. (canceled)

20. The natural stone panel according to claim 1, wherein the sensing electrode bottom section comprise a thickness of at least 20 microns.

21. The natural stone panel according to claim 1, wherein the shielding tracks are placed around the sensing electrode, at a distance of at least 1 cm.

22. The natural stone panel according to claim 1, wherein the shielding tracks occupy an area with a length of at least 9.5 cm.

23. (canceled)

24. The natural stone panel according to claim 1, wherein the shielding tracks have a thickness of at least 20 microns.

25. The natural stone panel according to claim 1, wherein the shielding tracks have a width of at least 1 mm.

26. (canceled)

27. The natural stone panel according to claim 1, wherein the sensing tracks comprise materials with sheet resistivities comprised range between 10 mΩ/sq/mil and 20 mΩ/sq/mil.

28. (canceled)

29. A method for manufacturing a natural stone panel with an integrated touch capacitive sensing system for placing as a touch detection facade, in direct contact with a wall, said method comprising:
providing a stone tile;
printing a sensing layer on said tile comprising a plurality of conductive tracks;
curing of silver and/or copper and/or aluminum tracks at temperatures comprised between 100° C. and 150° C., for 10 minutes to 20 minutes;
printing a shielding layer on said tile comprising a plurality of conductive tracks; and
applying an insulating layer for providing moisture and electrical insulation between the printed sensing and shielding layers and the wall;
wherein the sensing tracks have been printed using a first ink, and the shielding tracks have been printed using a second ink, wherein electrical conductivity of the first ink is lower or equal than electrical conductivity of the second ink.

30. (canceled)

31. (canceled)

32. The method for manufacturing a natural stone panel according to claim 29, wherein a plurality of copper wires is soldered to the copper tape and connected to a control circuit.
